(19) United States
(12) Patent Application Publication
(10) Pub. No.: US 2025/0372446 A1
(43) Pub. Date: Dec. 4, 2025

(54) SEMICONDUCTOR DEVICES HAVING AIR GAPS AND METHODS FOR MANUFACTURING THE SAME

(71) Applicant: Winbond Electronics Corp., Taichung City (TW)

(72) Inventors: Pei-Wen CHEN, Taichung City (TW); Cheng-Shuai LI, Taichung City (TW); Kao-Tsair TSAI, Taichung City (TW)

(21) Appl. No.: 19/223,528

(22) Filed: May 30, 2025

(30) Foreign Application Priority Data
May 30, 2024 (TW) 113120030

(51) Int. Cl. H01L 21/764; H10B 12/00; H10B 41/40; H10D 84/01; H10D 84/83

(52) U.S. Cl. CPC H01L 21/764; H10B 41/40; H10B 12/50; H10D 84/0151; H10D 84/83

(57) ABSTRACT

A semiconductor device includes several gate stacks over a substrate, a first insulating layer over the gate stacks and a second insulating layer. The gate stacks extend in the first direction and are separated from each other in the second direction. There is an air gap between two adjacent gate stacks. The first insulating layer is disposed over the gate stacks and the air gaps. The first insulating layer exposes an end portion of each of the gate stacks. The second insulating layer is disposed on the first insulating layer and further covers the end portions of the gate stacks that are uncovered by the first insulating layer.

### CROSS REFERENCE TO RELATED APPLICATIONS

This application claims priority of Taiwan Patent Application No. 113120030, filed on May 30, 2024, the entirety of which is incorporated by reference herein.

### BACKGROUND

### Technical Field

The disclosure relates to semiconductor devices and methods for manufacturing the same, and it relates to semiconductor devices having air gaps and methods for manufacturing the same.

### Description of the Related Art

Currently, the trend in semiconductor manufacturing is development towards the miniaturization of components. This is accompanied by many challenges. For example, a shorter distance between the gate electrodes in a semiconductor device means a higher parasitic capacitance. The problem of threshold voltage interference occurs, which in turn affects the electrical performance of the semiconductor device, such as by causing read errors in flash memory.

In order to reduce parasitic capacitance, current manufacturing methods form a medium with a low dielectric coefficient, such as an air gap, between adjacent gate electrodes. According to the existing manufacturing process, overhangs are formed on the tops of the gate stacks, and then a capping layer is formed to cover the overhangs, thereby sealing the spaces between adjacent gate stacks to form air gaps. However, these overhangs that are formed according to the existing manufacturing processes exert uneven stress on the underlying gate stacks, which undesirably causes the gate stacks to bend. In addition, during the process of forming the capping layer, if the capping layer does not seal the spaces between the gate stacks in the peripheral region, it may provide one or more defective exhaust paths in subsequent processes, thereby affecting the structural reliability of the semiconductor device.

In addition, it is difficult to control the shapes and heights of the air gaps to be uniform in a semiconductor device. That is, those air gaps don't have substantially identical three-dimensional profiles and cross-sectional shapes. Accordingly, the parasitic capacitances between different gate electrodes differ greatly, which affects the reliability of the electrical properties of the semiconductor device. In addition, during the process of forming the overhangs or the capping layer, the overhangs or the capping layer would partially fill the spaces between the gate stacks, so that the air gaps become smaller or the tops of the air gaps are narrowed. The smaller air gaps and/or the air gaps with narrow tops are not conducive to interference decrease between the gate electrodes, thereby negatively affecting the write speed of the semiconductor device.

### SUMMARY

According to the semiconductor device with air gaps and its manufacturing method provided in the present disclosure, the problems of the conventional semiconductor device, such as the air gaps with non-uniformed profile or height, the bended gate stacks due to the conventional air gap formation process, and the conventional air gaps not conducive to reducing the interference between the gate electrodes, can be solved.

Embodiments of the present disclosure provide a semiconductor device. The semiconductor device includes several gate stacks disposed over a substrate, a first insulating layer formed over the gate stacks and a second insulating layer formed on the first insulating layer. The gate stacks extend in the first direction and are separated from each other in the second direction. There is an air gap between every two adjacent gate stacks. The first insulating layer is formed over the gate stacks and the air gaps. The first insulating layer exposes an end portion of each of the gate stacks. The second insulating layer covers the end portions of the gate stacks that are outside and uncovered by the first insulating layer.

Embodiments of the present disclosure provide a method for manufacturing a semiconductor device. The method includes forming several gate stacks over a substrate, wherein the gate stacks extend in the first direction and are separated from each other in the second direction. There is a space between every two adjacent gate stacks. The method further includes forming a first insulating layer over the gate stacks and the spaces, wherein the first insulating layer exposes an end portion of each of the gate stacks. The method further includes forming a second insulating layer on the first insulating layer. The second insulating layer covers the end portions of the gate stacks that are uncovered by the first insulating layer. The second insulating layer seals the opposite ends of each of the spaces, thereby forming an air gap between every two adjacent gate stacks.

According to the semiconductor device and its manufacturing method provided by the present disclosure, the heights of the air gaps in the semiconductor device can be well controlled, and the air gaps can have uniform three-dimensional profiles and cross-sectional shapes. According to the manufacturing method of the embodiments, the maximum space between adjacent gate stacks can be obtained, thereby reducing parasitic capacitance between adjacent gate stacks. Accordingly, the electrical performance of the semiconductor device can be improved.

### BRIEF DESCRIPTION OF THE DRAWINGS

FIG. 1, FIG. 2, FIG. 3, FIG. 4A-FIG. 4D, FIG. 5A, FIG. 5B, FIG. 6A-FIG. 6D, FIG. 7A and FIG. 7B illustrate various intermediate stages for manufacturing a semiconductor device, in accordance with some embodiments of the present disclosure.

FIG. 8 is a schematic diagram of a semiconductor device after the second insulating layer is formed, in accordance with some embodiments of the present disclosure.

### DETAILED DESCRIPTION

The present invention will be described in more detail below with reference to the accompanying drawings. To simplify the descriptions and drawings, drawings merely show an array region or a portion of the array region of a semiconductor device. However, the present invention can be embodied in various reasonable combinations that are defined within the scope of the present invention. The following contents provide different embodiments or examples for implementing different features of the provided subject matter. These are, of course, only examples and are not intended to limit the disclosure. In addition, for the purposes of simplicity and clarity, the embodiments of the present disclosure may use the same or similar reference numbers for designating the same or similar components in many examples, which may not be repeatedly described in some of the embodiments.

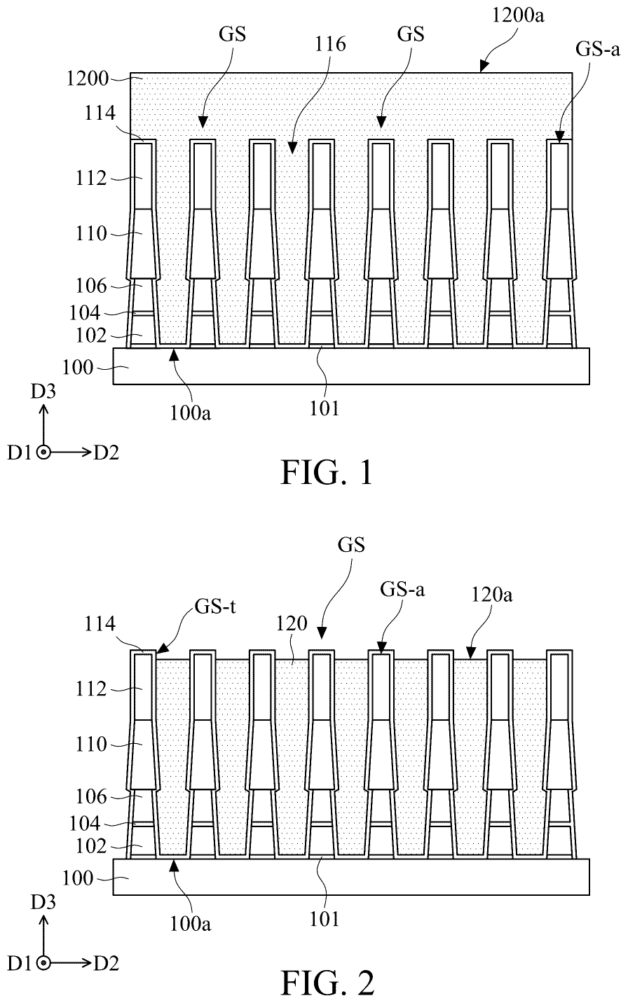

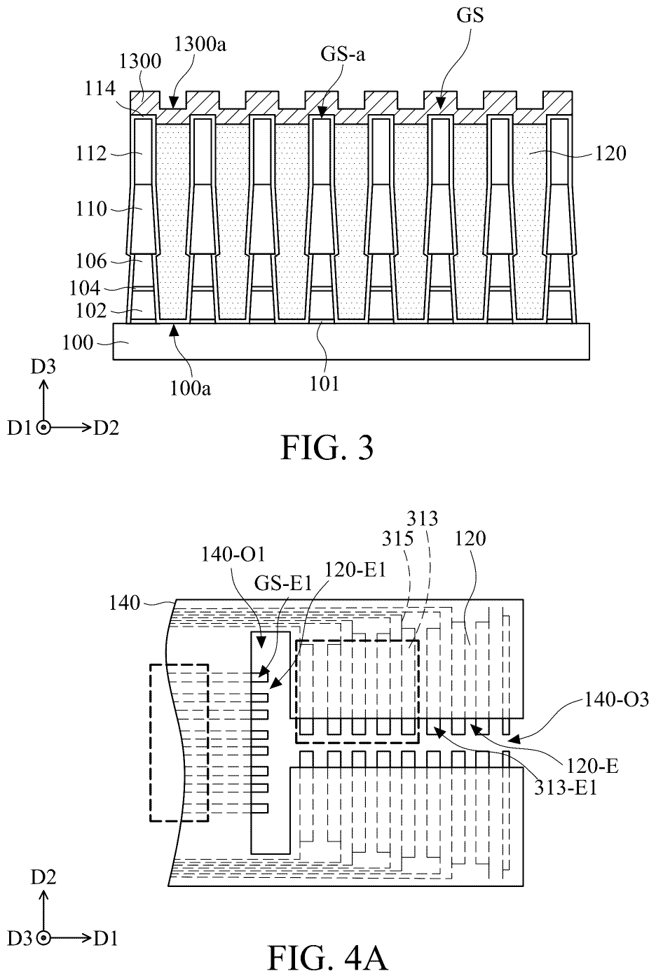

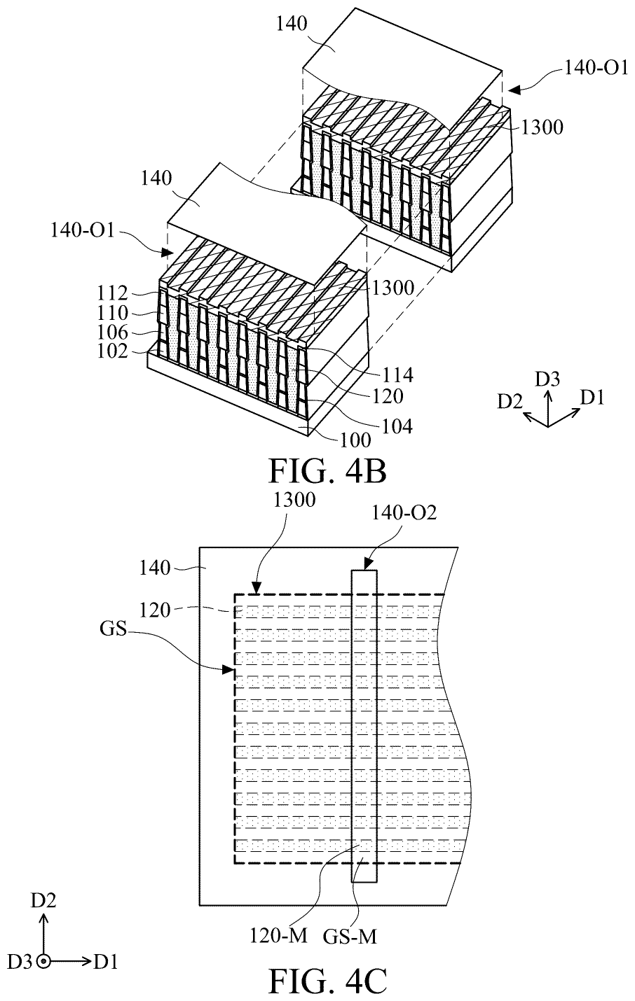

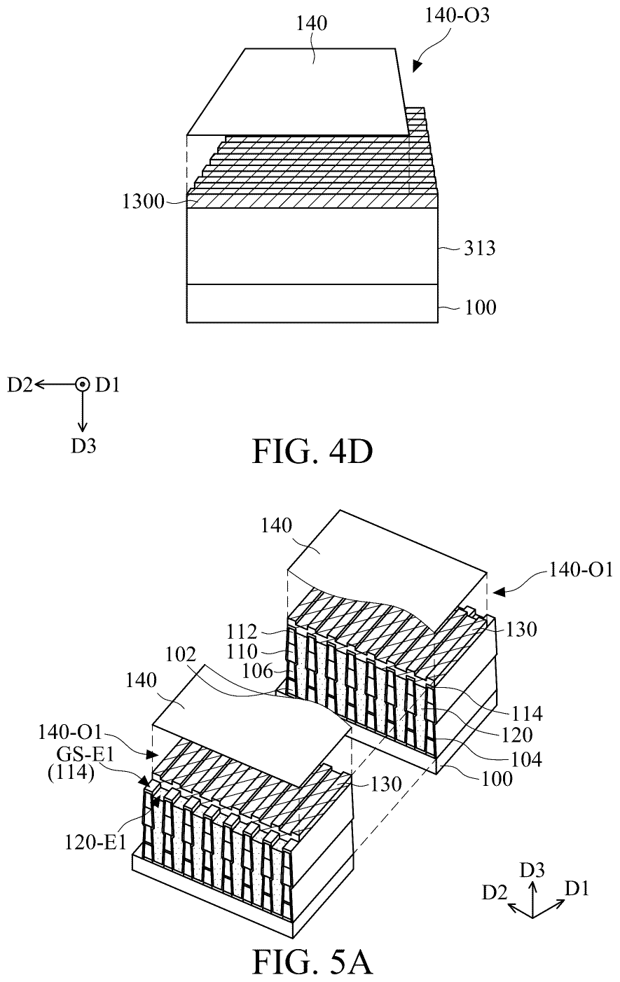

Referring to FIG. 1, a substrate 100 is provided, and several gate stacks GS are formed over the substrate 100, in accordance with some embodiments of the present disclosure. The gate stacks GS are formed, for example, in the array region of the substrate 100. The gate stacks GS extend in the first direction D1 and are separated from each other in the second direction D2. There is a space 116 between every two adjacent gate stacks GS.

In some embodiments, the substrate 100 may include silicon, gallium arsenide, gallium nitride, silicon germanium, silicon on insulator (SOI), another suitable material, or a combination of the foregoing materials.

In this exemplary embodiment, each of the gate stacks GS includes, for example, a tunnel dielectric layer 101, a floating gate electrode 102, an inter-gate dielectric layer 104, a control gate 106, a conductive contact layer 110 and a hard mask 112 that are sequentially formed on the substrate 100 (i.e., in the third direction D3). In some embodiments, the material of the tunnel dielectric layer 101 includes silicon oxide or a high dielectric constant material (the dielectric constant is, for example, greater than 4). The foregoing high dielectric constant materials may include, for example, hafnium oxide, hafnium silicon oxide, hafnium aluminum oxide, hafnium tantalum oxide, or another suitable dielectric material. In some embodiments, the floating gate electrode 102 includes polysilicon or another suitable conductor material. The inter-gate dielectric layer 104 may be a single layer structure or a multi-layer structure. The inter-gate dielectric layer 104 may include silicon oxide, silicon nitride, another suitable dielectric material, or a combination thereof. The control gate electrode 106 may be a single layer structure or a multi-layer structure. In some embodiments, the material of the control gate 106 includes polysilicon, metal, metal silicide, another suitable conductive material, or a combination of the foregoing material. For example, metal may include titanium (Ti), tantalum (Ta), tungsten (W), aluminum (Al), zirconium (Zr), or a combination thereof. Metal silicide may include nickel silicide, titanium silicide, tungsten silicide, or cobalt silicide. In addition, in some embodiments, the conductive contact layer 110 includes, for example, tungsten or another suitable conductive material. The hard mask 112 that is disposed on the conductive contact layer 110 includes, for example, silicon nitride or another suitable mask material.

In addition, in some embodiments, a lining layer 114 may be conformally formed over the substrate 100 and the gate stacks GS in order to protect the surfaces of the gate stacks GS and the portions of the top surface 100a of the substrate 100 that are located in the spaces 116. The lining layer 114 may include an oxide, such as silicon oxide, and may be formed over the substrate 100 and the gate stacks GS by any suitable process, for example, an atomic layer deposition (ALD) process.

After the gate stacks GS are formed, a sacrificial material 1200 is formed over the substrate 100 and the gate stacks GS, in accordance with some embodiments of the present disclosure. The sacrificial material 1200 fills the spaces 116 between the gate stacks GS. In addition, the top surface 1200a of the sacrificial material 1200 is, for example, higher than the top surfaces GS-a of the gate stacks GS.

The sacrificial material 1200 includes one or more materials with high fluidity, and can fills the spaces 116 between the gate stacks. In addition, the sacrificial material 1200 can be easily removed during subsequent processes. In one exemplary embodiment, the sacrificial material 1200 includes a negative photoresist. The characteristic of negative photoresist is that the negative photoresist will be cross-linked into long-chain molecules when it is exposed. The cross-linked long-chain molecules are not easily dissolved by the developer. Therefore, the exposed portions of the negative photoresist will be remained while the unexposed portions will be dissolved by the developer during the development process. In some embodiments, the sacrificial material 1200 that includes a negative photoresist can be formed above the substrate 100 by a coating process (such as a spin coating process). The sacrificial material 1200 that excessively formed on the gate stacks GS covers the gate stacks GS and fully fills the spaces 116 between the gate stacks GS.

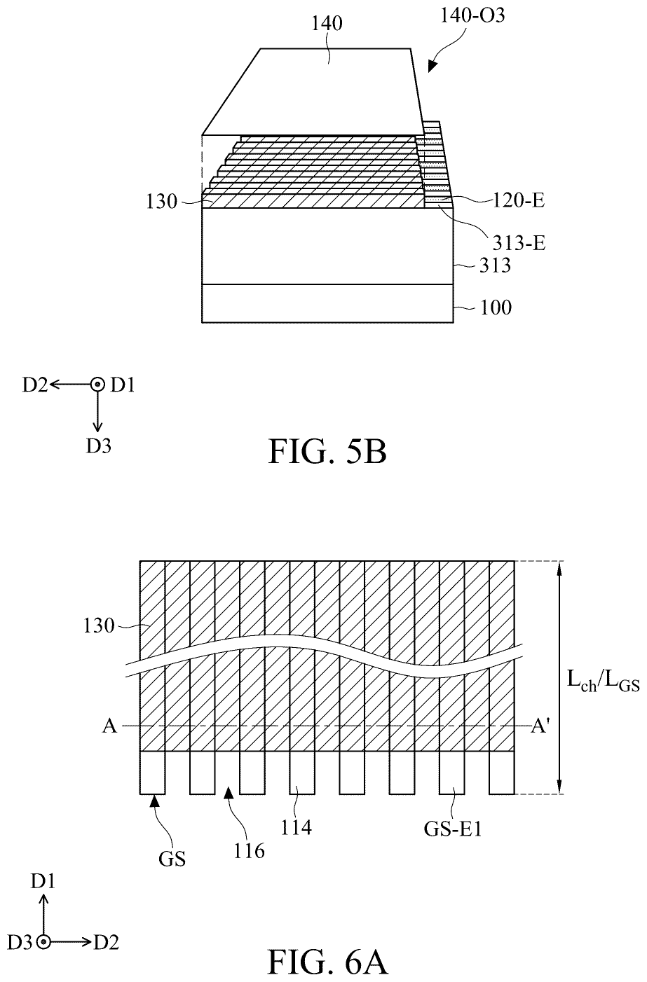

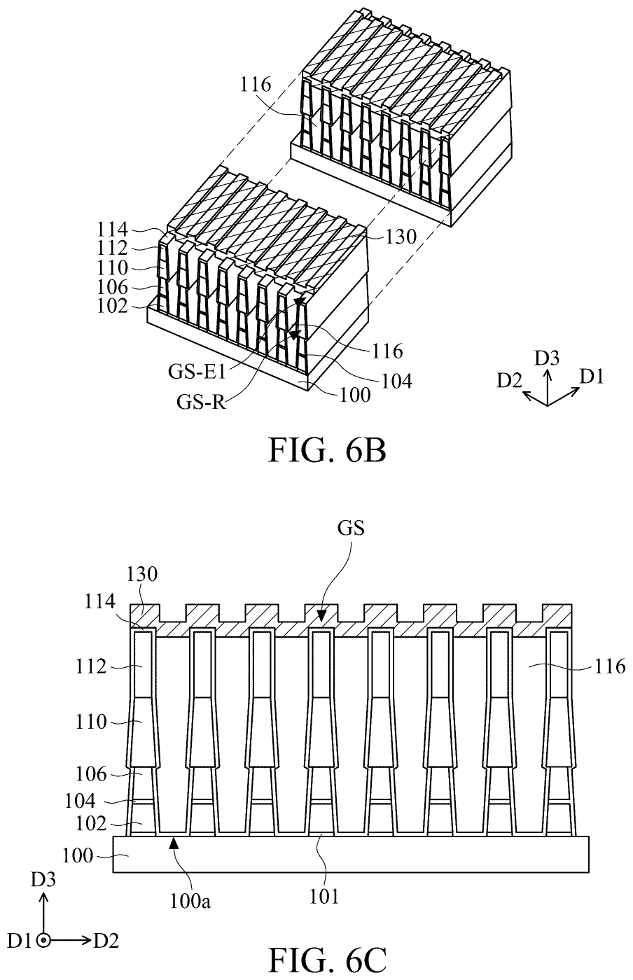

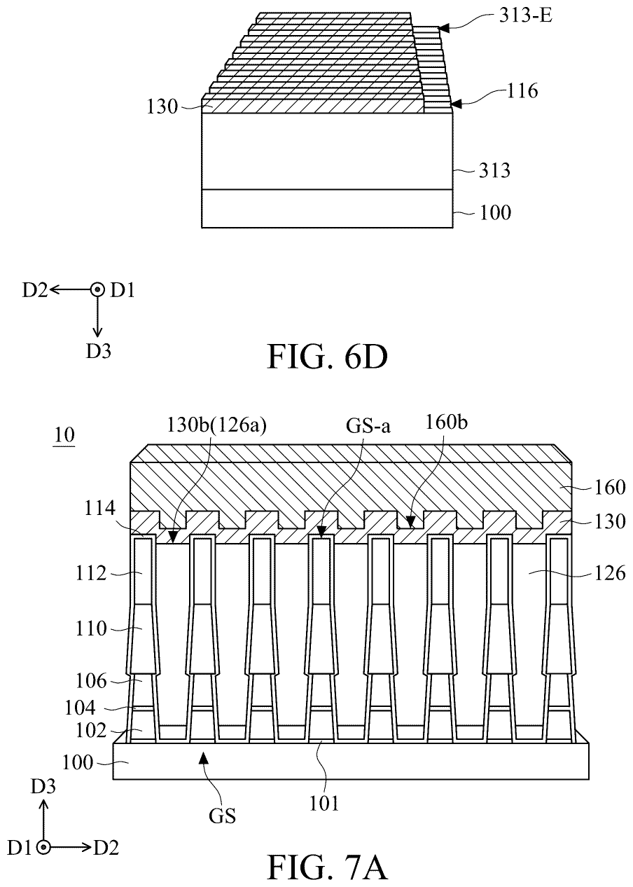

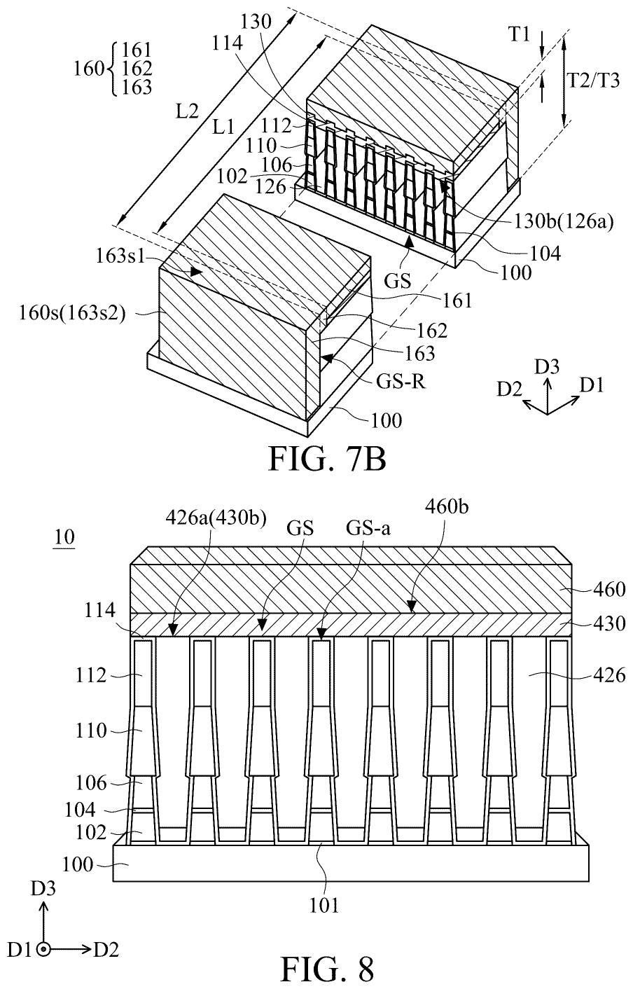

Referring to FIG. 2, a portion of the sacrificial material 1200 is removed, and the remaining portions of the sacrificial material 1200 form a sacrificial layer 120, in accordance with some embodiments of the present disclosure. The sacrificial layer 120 at least exposes the top surfaces GS-a of the gate stacks GS. For example, the top surface of the sacrificial layer 120 and the top surfaces GS-a of the gate stacks GS may be substantially located on the same horizontal level (as shown in FIG. 8, and the details will be described later). In some embodiments, the top surface of the sacrificial layer 120 may be slightly lower than the top surfaces GS-a of the gate stacks GS, as shown in FIG. 2. In a preferred embodiment, when the top surface of the sacrificial layer 120 is slightly lower than the top surfaces GS-a of the gate stacks GS, the electrical defects that may be caused by the sacrificial material 1200 remaining at the top corners of the gate stacks GS can be effectively prevented.

In some embodiments, the sacrificial layer 120 may have a substantially flat top surface 120a. For example, the top surface 120a of the sacrificial layer 120 is substantially parallel to the top surface 100a of the substrate 100. In some preferred embodiments, the height difference between the top surface 120a of the sacrificial layer 120 and the top surfaces GS-a of the gate stacks GS may be in a range of, for example, 1% to 10% of the total height of the gate stacks GS. This makes it easy to maximize the height of the air gaps between gate stacks GS while the aforementioned electrical defects can be effectively avoided.

In addition, in this exemplary embodiment, it should be noted that no sacrificial material 1200 remains on the tops GS-t of the gate stacks GS, especially no residue of the sacrificial material 1200 remains at the corners of the top surfaces GS-a and the lateral surfaces of the tops GS-t of the gate stacks GS. The aforementioned electrical defects can be avoided by exposing the tops GS-t of the gate stacks GS. In addition, the adhesion between the gate stacks GS and an insulating material layer 1300 that is subsequently formed can be improved.

Next, referring to FIG. 3, an insulating material layer 1300 is formed on the sacrificial layer 120, in accordance with some embodiments of the present disclosure. The insulating material layer 1300 includes, for example, one or more oxides, or another suitable insulating material. The insulating material layer 1300 can be formed by, for example, a physical vapor deposition (PVD) process, a chemical vapor deposition (CVD) process, an ALD process, or a combination of the foregoing processes.

In some embodiments, the insulating material layer 1300 can be deposited at a low temperature. For example, the insulating material layer 1300 is deposited at a temperature lower than the deposition temperature of the sacrificial material 1200, or at a temperature lower than the temperature for curing the sacrificial layer 120. Low deposition temperature of the insulating material layer 1300 prevents the underlying sacrificial layer 120 from being undesirable heating, thereby improving the removal efficiency for removing the sacrificial layer 120 in the subsequent process.

For example, in one example where the material of the sacrificial layer 120 is a negative photoresist, deposition of the insulating material layer 1300 at a temperature lower than the temperature at which the negative photoresist is cross-linked and hardened can prevent the underlying sacrificial layer 120 from being heated by the insulating material layer 1300. Heating the sacrificial layer 120 will make the negative photoresist to be partially or completely cross-linked and hardened, thereby increasing the difficulty of subsequent removal of the sacrificial layer 120.

In one embodiment, the insulating material layer 1300 may include low temperature oxide (LTOX). In a preferred embodiment, the top surface of the sacrificial layer 120 may be slightly lower than the top surfaces GS-a of the gate stacks GS, and the LTOX may be conformally formed on the top surface of the sacrificial layer 120, the top surfaces GS-a and upper portions of the sidewalls of the gate stacks GS. Therefore, the surface of the insulating material layer 1300 defines several recesses above the sacrificial layer 120. In addition, in the embodiments where the lining layer 114 includes ALD oxide, use of the insulating material layer 1300 that includes LTOX may improve the adhesion between the insulating material layer 1300 and the underlying lining layer 114.

In this exemplary embodiment, the top surface 1300a of the insulating material layer 1300 that are positioned correspondingly above the sacrificial layer 120 is not lower than the top surfaces GS-a of the adjacent gate stacks GS, thereby easily forming the air gaps that have the maximum height.

Referring to FIG. 4A to FIG. 4D, a mask 140 is provided above the insulating material layer 1300, in accordance with some embodiments of the present disclosure. FIG. 4A is a top view of the mask 140, and illustrates only a portion of the array region of the semiconductor device. FIG. 4B is a schematic diagram of the position of the mask 140, wherein the middle portion of the gate stacks GS is omitted in FIG. 4B. FIG. 4C is a partially enlarged schematic diagram of a structure that is drawn based on the left dashed box of FIG. 4A. In this exemplary embodiment, the mask 140 has an opening 140-O1. The position of the opening 140-O1 corresponds to the end portions GS-E1 of the gate stacks GS and the end portion 120-E1 of the sacrificial layer 120 that are under the insulating material layer 1300. In addition, as shown in FIG. 4C, in some embodiments, besides the opening 140-O1, the mask 140 may have another opening 140-O2. The position of the opening 140-O2 corresponds to an inactive bit region in the array region. For example, the position of the inactive bit region corresponds to the middle portions GS-M of the gate stacks GS that extend in the first direction D1. The opening 140-O2 also exposes the middle portions 120-M of the sacrificial layer 120, thereby improving the efficiency for removing the sacrificial layer 120 in the subsequent process. However, the present disclosure is not limited thereto.

In addition, in some embodiments, as shown in FIG. 4A, the semiconductor device may have several pickup electrodes 313 and several wire traces 315 that connect the corresponding gate stacks GS and the pickup electrodes 313. In the aforementioned steps, the sacrificial layer 120 can also fill the spaces between adjacent pickup electrodes 313, and the insulating material layer 1300 is formed on the sacrificial layer 120 between the pickup electrodes 313 (shown in FIG. 4D). FIG. 4D is a side perspective view of a structure, including the pickup electrodes 313 and the mask 140, that are drawn based on the right dashed box of FIG. 4A and viewed from the first direction D1. As shown in FIG. 4D, the mask 140 may have an opening 140-O3 that are provided above the end portions 313-E of the pickup electrodes 313 and the end portions 120-E of the sacrificial layer 120 between the pickup electrodes 313. Accordingly, several air gaps between the pickup electrodes 313 can be formed in the subsequent steps due to the opening 140-O3 of the mask 140, thereby reducing electrical interference between the gate stacks GS. These openings 140-O1, 140-O2 and 140-O3 are provided to define the positions where the insulating material layer 1300 is removed in subsequent step. In this exemplary embodiment, the opening 140-O1 and the opening 140-O3 extend in different directions and are connected to each other.

Referring to FIG. 5A, a portion of the insulating material layer 1300 is removed through the opening of the mask 140, in accordance with some embodiments of the present disclosure. Accordingly, the end portions GS-E1 of the gate stacks GS and the end portions 120-E1 of the sacrificial layer 120 are exposed. In some embodiments, the portions of the insulating material layer 1300 that are located under the openings 140-O1, 140-O2 and 140-O3 of the mask 140 can be removed through lithography and etching processes. The remaining portions of the insulating material layer 1300 form the first insulating layer 130. The first insulating layer 130 exposes the end portions GS-E1 of the gate stacks GS and the end portions 120-E1 of the sacrificial layer 120. In an embodiment in which the mask 140 has an opening 140-O2 provided corresponding to the inactive bit region, the first insulating layer 130 also exposes the portions of the gate stacks GS and the sacrificial layer 120 that are positioned in the inactive bit region. In an embodiment in which the mask 140 has an opening 140-O3 provided corresponding to the end portions 313-E of the pickup electrodes 313 and the end portions 120-E of the sacrificial layer 120 between the pickup electrodes 313, the first insulating layer 130 further exposes the end portions 313-E of the pickup electrodes 313 and the end portions 120-E of the sacrificial layer 120 between the pickup electrodes 313, as shown in FIG. 5B.

In one exemplary embodiment, after the first insulating layer 130 is formed, the lining layer 114 that is conformally formed on the gate stacks GS and covers the gate stacks GS is exposed. After one or more portions of the insulating material layer 1300 are removed, the mask 140 is removed.

Referring to FIG. 6A to FIG. 6D, after the first insulating layer 130 is formed, the sacrificial layer 120 is removed to form a space 116 between two adjacent gate stacks GS. The extension lengths L_{ch} of these spaces 116 in the first direction D1 and the extension lengths Los of the gate stacks GS in the first direction D1 are substantially the same. As shown in FIG. 6D, in an embodiment in which the first insulating layer 130 further exposes the end portions 313-E of the pickup electrodes 313 and the end portions 120-E of the sacrificial layer 120 between the pickup electrodes 313, a space 116 is formed between two adjacent pickup electrodes 313 after the sacrificial layer 120 is removed.

FIG. 6A is a partial top view of a structure after the sacrificial layer 120 is removed. FIG. 6B is a perspective view of a structure after the sacrificial layer 120 is removed. FIG. 6C is a cross-sectional view of a structure after the sacrificial layer 120 is removed, which corresponds to the position taken along line A-A′ of the structure in FIG. 6A. FIG. 6D is a side view of a structure after the sacrificial layer 120 is removed. At this manufacturing stage, the spaces 116 extend under the first insulating layer 130, and the first insulating layer 130 acts as a cap to shield most of the spaces 116 and cover most portion of each of the gate stacks GS, in accordance with some embodiments of the present disclosure.

In some embodiments, the sacrificial layer 120 can be partially exposed (for example, the end portions 120-E1 are exposed). Next, the sacrificial layer 120 can be completely removed using a development and dissolution process to form the spaces 116 at the position of the sacrificial layer 120. For example, an organic solvent may be used to dissolve and remove the sacrificial layer 120. In some embodiments where the sacrificial layer 120 includes a negative photoresist, the sacrificial layer 120 can be removed by using a developer solution that has high solubility for the negative photoresist.

In addition, in some embodiments, after the sacrificial layer 120 is removed using a developer solution, subsequent steps such as air extraction, low-temperature heating, and cleaning with a highly volatile solvent may be performed to remove the moisture from the structure. Examples of the highly volatile solvent may include isopropyl alcohol or another suitable solvent. The cleaning step of low-temperature heating and/or the use of highly volatile solvent does not damage the gate stacks GS and its related components.

Next, referring to FIG. 7A and FIG. 7B, a second insulating layer 160 is formed on the first insulating layer 130 and the end portions GS-E1 of the gate stacks GS to seal these spaces 116, thereby forming air gaps 126 between every two adjacent gate stacks GS. FIG. 7A is a schematic cross-sectional view of a structure after the second insulating layer 160 is formed. FIG. 7B is a perspective view of a structure after the second insulating layer 160 is formed. The second insulating layer 160 extends in the first direction D1 to cover the end portions GS-E1 of the gate stacks GS that are positioned outside and uncovered by the first insulating layer 130, in accordance with some embodiments of the present disclosure. For example, the second insulating layer 160 covers the top surfaces and lateral surfaces of the end portions GS-E1. In addition, the second insulating layer 160 may further extend to cover the back surfaces GS-R of the end portions GS-E1 of the gate stacks GS. In the embodiment in which the first insulating layer 130 further exposes the end portions 313-E of the pickup electrodes 313 and the end portions 120-E of the sacrificial layer 120 between the pickup electrodes 313, the second insulating layer 160 is also formed on the end portions 313-E of the pickup electrodes 313 to seal the spaces 116 between the pickup electrodes 313. Thus, air gaps 126 are formed between the pickup electrodes 313 after the second insulating layer 160 is formed. Before or after the air gaps 126 are formed, other related components that are required in the structure may be formed through known processes to complete a desired semiconductor device 10.

In this exemplary embodiment, the semiconductor device 10 includes several gate stacks GS that are formed on the substrate 100. Each of the gate stacks GS extends in the first direction D1, and the gate stacks are separated from each other in the second direction D2. There is an air gap 126 between every two adjacent gate stacks. The first insulating layer 130 is formed on the gate stacks GS and the air gaps 126 and exposes the end portions GS-E1 of the gate stacks GS. The second insulating layer 160 is formed on the first insulating layer 130 and covers the end portions GS-E1 of the gate stacks GS. In some embodiments, the top surfaces 126a of the air gaps 126 are no lower than the bottom surfaces of the hard masks 112 of the gate stacks GS.

The second insulating layer 160 may include a single layer or multiple layers of suitable insulating materials. For example, the second insulating layer 160 may include one or more oxygen-containing insulating materials, one or more nitrogen-containing insulating materials, or another flowable insulating material. In one example, the second insulating layer 160 includes an oxide material, such as (but not limited to) tetraethoxysilane (TEOS).

The second insulating layer 160 fills the portions of the spaces 116 between the end portions GS-E1 of the gate stacks GS to seal the ends of the spaces 116, in accordance with some embodiments of the present disclosure. The remaining portions of the spaces 116 form the air gaps 126. In addition, the second insulating layer 160 can seal the spaces between the gate stacks in the peripheral region to avoid providing defective exhaust path in the subsequent processes, thereby improving the structural reliability of the semiconductor device.

In some embodiments, the air gaps 126 that are beneath the first insulating layer 130 extend in the first direction D1. The bottom surface 130b of the first insulating layer 130 defines the top surfaces 126a of the air gaps 126. In addition, in some embodiments, the sacrificial layer 120 has a flat top surface 120a (as shown in FIG. 2 and FIG. 3). Therefore, the air gaps 126 that are formed by removing the sacrificial layer 120 to form spaces 116 and sealing the ends of the spaces 116 have flat top surfaces 126a.

In addition, since the second insulating layer 160 seals the ends of the spaces 116, the opposite ends of the air gaps 126 are in direct contact with the second insulating layer 160 in the first direction D1.

In addition, according to the method of the embodiment, the first insulating layer 130 does not fill the space 116. There is no second insulating layer 160 in the air gaps 126 except the air gap portions between the end portions GS-E1 of the gate stacks GS or the end portions 313-E1 of the pickup electrodes 313. Accordingly, compared to the conventional method for forming air gaps between the gate stacks, there is no dielectric/insulating material residual remained on the sidewalls of the gate stacks GS that is manufactured by the embodied method. As shown in FIG. 7A, only the lining layer 114 and the air gap 126 exist between the conductive materials (such as the conductive contact layers 110) of the gate stacks GS. In addition, the volume of the air gap 126 is significantly greater than the volume of the lining layer 114. Therefore, the air gaps 126 that are formed by the manufacturing method of the embodiment can suppress parasitic capacitance between adjacent gate stacks GS to the maximum extent.

In addition, in some embodiments, the gate stacks GS and the air gaps 126 extend in the same direction (for example, extend in the first direction D1). However, the first insulating layer 130 does not completely cover the gate stacks GS (i.e., expose the end portions GS-E1 of the gate stacks GS), and the second insulating layer 160 fills the spaces between the end portions GS-E1 of the gate stacks GS, thereby sealing both ends of each of the space 116. Therefore, the extension length of the air gaps 126 is less than the extension length of the gate stacks GS. As shown in FIG. 7B, the first length L1 of the air gaps 126 in the first direction D1 is less than the second length L2 of the gate stacks GS in the first direction D1.

Specifically, the second insulation layer 160 may be divided into a first part 161, a second part 162 and a third part 163, in accordance with some embodiments of the present disclosure. The first part 161 is positioned above the first insulating layer 130 and has the thickness T1. The second part 162 is positioned outside the first insulating layer 130 and fills the space 116 between the end portions GS-E1 of the gate stacks GS. The second part 162 has the thickness T2. The third part 163 of the second insulation layer 160 covers the exposed back surfaces GS-R of the end portions GS-E1 of the gate stacks GS. In addition, the third part 163 extends to the substrate 100, and has the thickness T3. For example, the third part 163 is in contact with the portions of the lining layer 114 on the substrate 100.

In some embodiments, the thickness T2 of the second part 162 and the thickness T3 of the third part 163 are both greater than the thickness T1 of the first part 161, and the thickness T2 is not greater than the thickness T3. When the second insulating layer 160 includes one or more insulating materials with good filling characteristics, the thickness T2 may be equal to the thickness T3. This ensures that the spaces between the gate stacks in the peripheral region are well sealed to avoid providing defective exhaust paths in the subsequent processes, thereby improving the structural reliability of the semiconductor device.

In addition, the third part 163 includes an inner sidewall 163s1 that connects the second part 162 and an outer sidewall 163s2 that is away from the gate stacks GS. The outer sidewall 163s2 of the third part 163 is also referred to as a flat sidewall 160s of the second insulating layer 160.

According to the aforementioned descriptions, the air gaps 126 that are formed by the method in some embodiments of the present disclosure may have the same profile, such as a uniform three-dimensional profile and cross-sectional shape, as shown in FIG. 7A. Therefore, the cross-sections of the air gaps 126 of the embodiment would not differ in width and/or height as air gaps formed by the conventional processes. In addition, the air gaps 126 that are formed by the method in some embodiments have flat top surfaces 126a, rather than narrow top surfaces like the air gaps formed by the conventional processes. In this exemplary embodiment, each of the air gaps 126 has a cross-sectional shape that is wide at the top and narrow at the bottom in the second direction D2. However, the present disclosure is not limited to this cross-sectional shape. The cross-sectional shape of the air gap 126 is varied and determined by the sidewalls of the laminated layers of the gate stack GS.

Therefore, through the manufacturing method of the present disclosure, the air gaps that are positioned between components in different regions (for example, the air gaps between the gate stacks GS and the air gaps between the pickup electrodes 313) can be formed simultaneously by the method of the embodiments, thereby simplifying the processes for manufacturing the air gaps.

FIG. 8 is a schematic diagram of a variation of the semiconductor device 10 after the second insulating layer is formed. The features/components in FIG. 8 similar or identical to the features/components in FIG. 7A are designated with similar or the same reference numbers. The details of those similar or the identical features/components, including the manufacturing method and formed structures, can be referred to the steps illustrated in FIG. 1 to FIG. 7B in the embodiment, and are not repeated herein.

According to the embodiment shown in FIG. 7A, the first insulating layer 130 is conformally deposited on the top surfaces and lateral surfaces of the tops of the gate stacks GS, so that the first insulating layer 130 is conformally deposited on the top surfaces and lateral surfaces of the tops of the gate stacks GS, so that the first insulating layer 130 has an undulating top surface and an undulating bottom surface. The difference between the structure in FIG. 7A and FIG. 8 is in the profiles of the first insulating layer 130/430 and the second insulating layer 160/460. According to the exemplified structure in FIG. 8, the sacrificial material is recessed to expose the top surfaces GS-a of the gate stacks GS, so that the top surface of the sacrificial layer (not shown in FIG. 8) is aligned with the top surfaces GS-a of the gate stacks GS. Thus, the first insulating layer 430 that is deposited on the sacrificial layer has a flat bottom surface 430b. For example, the bottom surface 430b of the first insulating layer 430 may be coplanar with the top surfaces GS-a of the gate stacks GS.

In addition, as shown in FIG. 8, after the sacrificial layer is removed and opposite ends of the spaces are sealed with the second insulating layer 460, the air gaps 426 are formed, and the top surfaces 426a of the air gaps 426 (defined by the bottom surface 430b of the first insulating layer 430) are substantially level with the top surfaces GS-a of the adjacent gate stacks GS.

In addition, unlike the structure shown in FIG. 7A in which the second insulating layer 160 has an undulating bottom surface 160b, in the exemplary embodiment shown in FIG. 8, the second insulating layer 460 has a flat bottom surface 460b.

According to the aforementioned descriptions, the semiconductor device and the method for manufacturing the same, in accordance with some embodiments of the present disclosure, have many advantages. The manufacturing method of the above embodiments may include, for example, forming a sacrificial layer, forming the first insulating layer that exposes the end portions of the gate stacks and the sacrificial layer, removing the sacrificial layer to form spaces between the gate stacks, and forming the second insulating layer to seal opposite ends of the spaces, thereby forming air gaps with flat top surfaces. Therefore, the heights of the air gaps can be well controlled, and the air gaps have uniform three-dimensional profile and cross-sectional shape, thereby improving the electrical performance and increasing the yield of the semiconductor device.

In addition, the air gaps that are manufactured according to the present disclosure can occupy the maximum space between the gate stacks, thereby suppressing the generation of parasitic capacitance. Especially when it is impossible to increase the spacing between adjacent gate stacks, or when the size of the semiconductor device is increasingly shrinking, the manufacturing method of the embodiments of the present disclosure can be applied to form the air gaps each having a maximum width between adjacent gate stacks, thereby reducing the parasitic capacitance. In addition, the semiconductor device that is manufactured by the present disclosure does not form overhanging portions that cover the respective tops of the gate stacks, thereby solving the bending problem of the gate stacks. In addition, the second insulating layer can seal the spaces between the gate stacks in the peripheral region to avoid providing defective exhaust paths in the subsequent processes, thereby improving the structural reliability of the semiconductor device.

In addition, according to the embodiments of the present disclosure, a semiconductor device with good electrical properties can be obtained, and the method for manufacturing the semiconductor device is simple and compatible with existing manufacturing processes. Thus, manufacture of the semiconductor device of the embodiments does not increase production costs and is suitable for mass production.

The semiconductor device with air gaps of the present disclosure can be a flash memory, a dynamic random access memory (DRAM) or a logic integrated circuit. The manufacturing method of the embodiments can be used to form the air gaps between the conductor patterns of the semiconductor device to reduce parasitic capacitance. The embodiments of the present disclosure are suitable for fabricating miniaturized semiconductor devices to increase the total number of dies on a wafer. Therefore, the present disclosure can reduce the production cost and power consumption for manufacturing a single IC, and reduce the power consumption of production in the subsequent packaging process, thereby reducing carbon emissions in the manufacturing process of semiconductor devices. In addition, since the yield and electrical performance of the semiconductor device of the present disclosure are improved, the present disclosure provides a green technology for semiconductor development.

What is claimed is:

1. A semiconductor device, comprising:
gate stacks disposed over a substrate, wherein the gate stacks extend in the first direction and are separated from each other in the second direction, and an air gap is formed between every two adjacent gate stacks;
a first insulating layer over the gate stacks and the air gaps, wherein the first insulating layer exposes an end portion of each of the gate stacks; and
a second insulating layer disposed on the first insulating layer, wherein the second insulating layer covers the end portions of the gate stacks that are uncovered by the first insulating layer.

2. The semiconductor device as claimed in claim 1, wherein the air gaps extend under the first insulating layer in the first direction until they are in contact with the second insulating layer, and the air gaps have flat top surfaces.

3. The semiconductor device as claimed in claim 1, wherein the second insulating layer fills spaces between the end portions of the gate stacks to seal opposite ends of each of the air gaps.

4. The semiconductor device as claimed in claim 1, wherein the air gaps have a first length in the first direction, the gate stacks have a second length in the first direction, and the first length is less than the second length.

5. The semiconductor device as claimed in claim 1, wherein the second insulating layer comprises:
a first part disposed on the first insulating layer, wherein the first part has a first thickness; and
a second part disposed outside the first insulating layer and filling spaces between the end portions of the gate stacks, wherein the second part has a second thickness, and the second thickness is greater than the first thickness; and
a third part covering exposed back surfaces of the end portions of the gate stacks that are uncovered by the first insulating layer.

6. The semiconductor device as claimed in claim 2, wherein each of the air gaps has a cross-sectional shape that is wider at a top of the air gap and narrower at a bottom of the air gap in the second direction.

7. The semiconductor device as claimed in claim 1, further comprising:
an oxide layer that is formed by atomic layer deposition (ALD) conformally covers the gate stacks, wherein the oxide layer formed by ALD is exposed in the air gaps.

8. The semiconductor device as claimed in claim 1, wherein a top surface of the first insulating layer that is above the air gaps is level with or higher than the top surfaces of the adjacent gate stacks.

9. The semiconductor device as claimed in claim 1, further comprising:
pickup electrodes formed on the substrate, and each of the pickup electrodes is electrically connected to one of the gate stacks,
wherein another air gap is formed between two adjacent pickup electrodes, and the first insulating layer is further formed on the pickup electrodes and the air gaps between the pickup electrodes, and
wherein the first insulating layer exposes an end portion of each of the pickup electrodes, and the second insulating layer covers the end portions of the pickup electrodes that are outside the first insulating layer.

10. A method for manufacturing a semiconductor device, comprising:
forming gate stacks over a substrate, wherein the gate stacks extend in the first direction and are separated from each other in the second direction, and there is a space between two adjacent gate stacks;
forming a first insulating layer over the gate stacks and the spaces, wherein the first insulating layer exposes an end portion of each of the gate stacks; and
forming a second insulating layer on the first insulating layer, and the second insulating layer covering the end portions of the gate stacks that are uncovered by the first insulating layer, wherein the second insulating layer seals opposite ends of each of the spaces, thereby forming an air gap between two adjacent gate stacks.

11. The method for manufacturing the semiconductor device as claimed in claim 10, wherein after the gate stacks are formed over the substrate, the method further comprises:
forming a sacrificial material over the substrate, wherein the sacrificial material covers the gate stacks and fills the spaces between the gate stacks;
removing a portion of the sacrificial material, wherein a remaining portion of the sacrificial material is referred to as a sacrificial layer, and the sacrificial layer exposes top surfaces of the gate stacks; and
forming an insulating material layer on the sacrificial layer.

12. The method for manufacturing the semiconductor device as claimed in claim 11, wherein the sacrificial material is recessed to expose lateral surfaces of tops of the gate stacks.

13. The method for manufacturing the semiconductor device as claimed in claim 11, wherein a bottom surface of the insulating material layer is coplanar with the top surfaces of the gate stacks.

14. The method for manufacturing the semiconductor device as claimed in claim 11, wherein the sacrificial layer is hardened at a first temperature, the insulating material layer is deposited on the sacrificial layer at a second temperature, and the second temperature is lower than the first temperature.

15. The method for manufacturing the semiconductor device as claimed in claim 11, wherein after the insulating material layer is formed on the sacrificial layer, the method further comprises:
providing a mask above the insulating material layer, wherein the mask has a first opening that corresponds to the end portions of the gate stacks and end portions of the sacrificial layer, and a second opening that corresponds to middle portions of the gate stacks and middle portions of the sacrificial layer that are extending in the first direction; and
removing a portion of the insulating material layer according to the mask, and remaining portions of the insulating material layer form the first insulating layer, wherein the first insulating layer exposes the end portions of the gate stacks and the end portions of the sacrificial layer at positions corresponding to the first opening, and
wherein the first insulating layer exposes the middle portions of the gate stacks and the middle portions of the sacrificial layer at positions corresponding to the second opening.

16. The method for manufacturing the semiconductor device as claimed in claim 15, wherein after the first insulating layer is formed, the method further comprises:
removing the sacrificial layer to expose the space between two adjacent gate stacks,
wherein the sacrificial layer includes a negative photoresist, and the negative photoresist is dissolved and removed using a developer solution.

17. The method for manufacturing the semiconductor device as claimed in claim 16, wherein after the sacrificial layer is removed, the second insulating layer is formed on the first insulating layer, and the second insulating layer covers the end portions of the gate stacks and fills ends portions of the spaces, wherein remaining portions of the spaces form the air gaps.

18. The method for manufacturing the semiconductor device as claimed in claim 17, wherein the second insulating layer further extends to cover back surfaces of the end portions of the gate stacks that are outside and uncovered by the first insulating layer.

19. The method for manufacturing the semiconductor device as claimed in claim 10, wherein the air gaps extend under the first insulating layer in the first direction until the air gaps are in contact with the second insulating layer, wherein the air gaps have flat top surfaces.

20. The method for manufacturing the semiconductor device as claimed in claim 10, further comprising:
pickup electrodes formed on the substrate, and each of the pickup electrodes is electrically connected to one of the gate stacks,
wherein another air gap is formed between two adjacent pickup electrodes, and the first insulating layer is further formed on the pickup electrodes and the air gaps between the pickup electrodes, and
wherein the first insulating layer exposes an end portion of each of the pickup electrodes, and the second insulating layer covers the end portions of the pickup electrodes that are outside the first insulating layer.
